(19) United States
(12) Patent Application Publication
(10) Pub. No.: US 2017/0086308 A1
(43) Pub. Date: Mar. 23, 2017

(54) DISPLAY DEVICE

(71) Applicant: Microsoft Technology Licensing, LLC, Redmond, WA (US)

(72) Inventors: Timothy Andrew Large, Bellevue, WA (US); Steven Bathiche, Kirkland, WA (US)

(21) Appl. No.: 14/857,559

(22) Filed: Sep. 17, 2015

(51) Int. Cl. H05K 5/00; H05K 5/02; G02B 5/18; G02B 5/04; G02B 3/08

(52) U.S. Cl. CPC H05K 5/0017; G02B 5/045; G02B 3/08; G02B 5/18; H05K 5/0226; G02B 2005/1804

(57) ABSTRACT

Embodiments are disclosed for configurations of optical components in a display device. An example display device includes a transparent outer layer including a first transparent panel and a second transparent panel, a display layer comprising a first display panel and a second display panel, and a gap positioned between the first display panel and the second display panel. The example display device also includes a first redirecting optical element positioned between the first transparent panel and the first display panel and a second redirecting optical element positioned between the second transparent panel.

### BRIEF DESCRIPTION OF THE DRAWINGS

FIG. 1 shows an example tiled display device.

FIGS. 2A and 2B show example views of an example hinged display device.

FIG. 3 shows a first example configuration of optical components in a display device.

FIG. 4A shows a second example configuration of optical components in a display device.

FIG. 4B shows an example cylindrical lens configuration in a display device.

FIG. 5 shows a detailed view of an example configuration of optical components in a display device.

FIG. 6 is a block diagram of an example computing system.

### DETAILED DESCRIPTION

Display devices may include display panels covered by protective glass, acrylic, or other transparent materials for allowing light to pass from the display panels to a user's eye. A support structure, such as a bracket, joint, hinge, or other structure, may house the display panel and/or the transparent material. However, the support structure may include edges or gaps that are visible to a user when viewing the display panel. In display devices such as tiled displays or hinged displays, where multiple display panels may be included and separated by one another via the support structure, the visibility of the support structure may hinder a user's perception of displayed objects. For example, an image that is continued from one display panel to a next display panel may be disrupted by a visible support structure.

In order to reduce and/or obscure the visibility of a support structure for a display panel, the present disclosure provides example display devices including curved or otherwise bent regions for directing light to a user's eye when the user's gaze is directed to a support structure at an edge of the display panel. In this way, when a user is viewing a region occupied by the support panel, the user may instead see light from the display panel showing the displayed object(s).

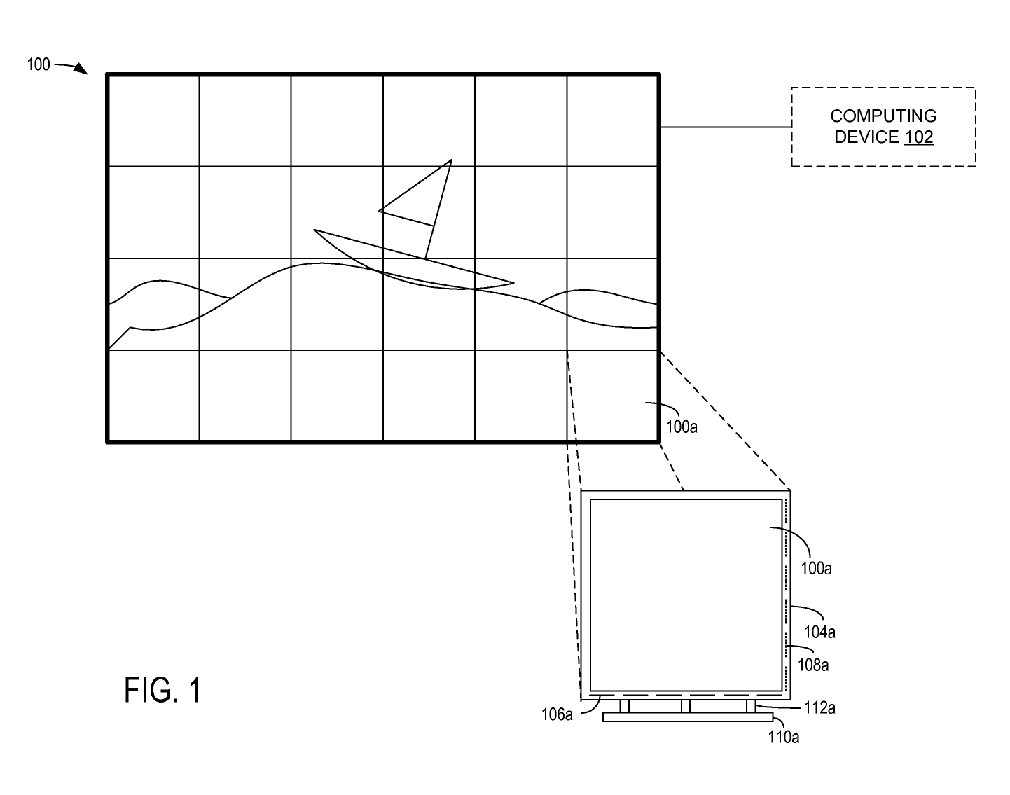

FIG. 1 shows an example tiled display device 100. As shown, an image (e.g., a boat in the illustrated example) may be continuously displayed across multiple display panels (e.g., including display panel 100a), such that a different portion of the image is displayed in each display panel of the tiled display device 100. Display device 100 may be coupled to a computing device 102 in some examples. The computing device 102 may send display instructions to display device 100 to control the display of images thereon. In other examples, display device 100 may include a processor, memory, image renderer, and/or any other suitable computing components to control the display of images via an integrated computing device.

A user may perceive the image displayed over the multiple display panels as a single image as long as the gaps between the display panels are maintained at a small size. If the gaps between the display panels are too large, the appearance of the displayed image may be degraded due to the interference of non-image material or space. In some scenarios, a user may even have difficulty in piecing together the displayed image due to the presence of large gaps within an image displayed across multiple display panels. It is therefore desirable to minimize gaps between different sections of image content. However, in tiled display devices, a large support structure for each display panel is often used to maintain structural integrity of the display device as a whole, to house display driving or other electrical components for each display panel, to provide an overall display device size/shape and/or other aesthetic feature for the display device, to promote sufficient heat transfer/air flow to cool the electrical components associated with the display device, to provide mechanical support and/or a mechanism for movement of the display panel, and/or to provide other features. Even in display devices without physical support structures (e.g., joints, brackets, or hinges) between the individual display panels, a gap (e.g., filled with air, adhesive material, heat transfer material, elastomeric material, and/or other materials) may be present between display panels for one or more of the reasons described above.

A detailed view of display panel 100a and related components is illustrated in FIG. 1. As shown in the detailed view, display panel 100a may be housed in a support structure 104a. The display panel 100a may include any suitable display panel, including but not limited to an organic light-emitting diode (OLED) panel, which may be used in flexible display devices, and a liquid crystal display (LCD) panel. An active area of the display panel (e.g., a series/array of light sources and/or elements for emitting light to a viewer of the display panel) is indicated by reference numeral 100a. The display panel may also include an edge seal for interfacing with support structure 104a. The edge seal may extend around a periphery of the active area of the display panel may provide a seal against debris/water, load distribution for pressure of the support structure on the display panel, mechanical shock absorption, and/or other protective features.

Support structure 104a may provide structural support for maintaining the display panel's position in the overall display device and for housing the circuitry provided to the display panel. The support structure 104a may extend over/around the edge seal of the display panel so as to avoid obscuring and/or damaging the active area of the display panel. In some examples, a display panel may be driven by row and column drivers that are positioned on different edges of the display panel. In such examples, drivers 106a may correspond to column drivers, and optional drivers 108a may correspond to row drivers. In other examples, both row and column drivers may be positioned along one edge of the display panel. In such examples, drivers 106a may correspond to row and column drivers for the display panel. Drivers 106a and/or 108a may receive control instructions and/or be powered by a printed circuit board (PCB) controller 110a via addressing/control/bus lines 112a. PCB controller 110a and/or another controller may be in communication with other electronic components of the display device. For example, a touch sensor(s) and/or touch panel may be positioned over the display panel and/or integrated within the display panel (e.g., a sensor-in-pixel configuration), and sensor data recorded by the touch sensor(s) may be transmitted to the connected controller. In some examples, electronic components associated with the touch sensor(s)/touch panel may be housed/positioned in an edge region of the display panel and/or in a support structure such as support structure 104a. In some examples, PCB controller 110a may be included in and/or in communication with an integrated computing device of the display device 100 and/or remote computing device 102.

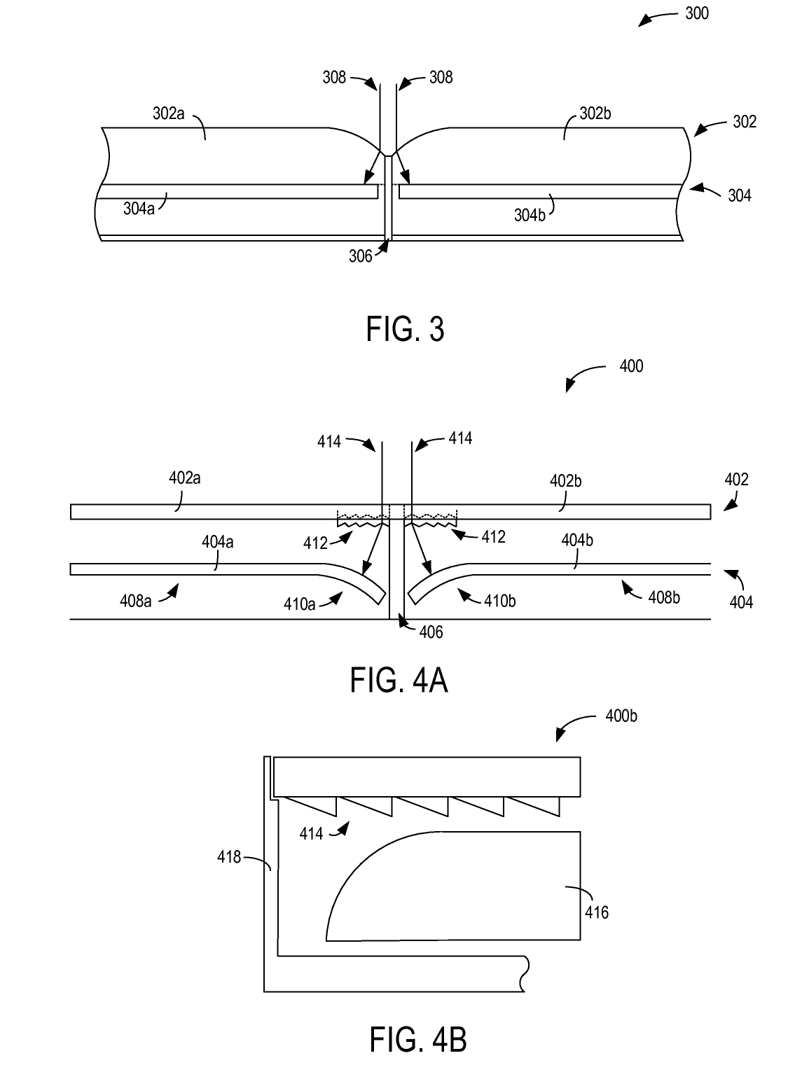

As shown, the componentry housed in support structure 104a may define a thickness of the support structure. The support structure may also be defined by an amount of structural support that is to be provided to maintain the position of the associated display panel in the overall display device 100 and/or a mechanical feature (e.g., a hinge, joint, and/or other mechanism) provided via the support structure. The configuration of display/optical components described below with respect to FIGS. 3-5 may be utilized to minimize the appearance of the support structure while allowing the physical size of the support structure to remain the size defined by the components/support specifications. The configurations described below with respect to FIGS. 3-5 may also be applied to obscure the appearance of any gap between display panels and/or between a display panel and an edge of a device (e.g., a display device chassis). Accordingly, references to a support structure below may be understood to apply equally or similarly to an edge region of the display device/display panel and/or a gap between the display panel and an edge of the device/another display panel, where the gap may not include a physical structure but may include material such as air, adhesive material, elastomeric material, and/or other materials.

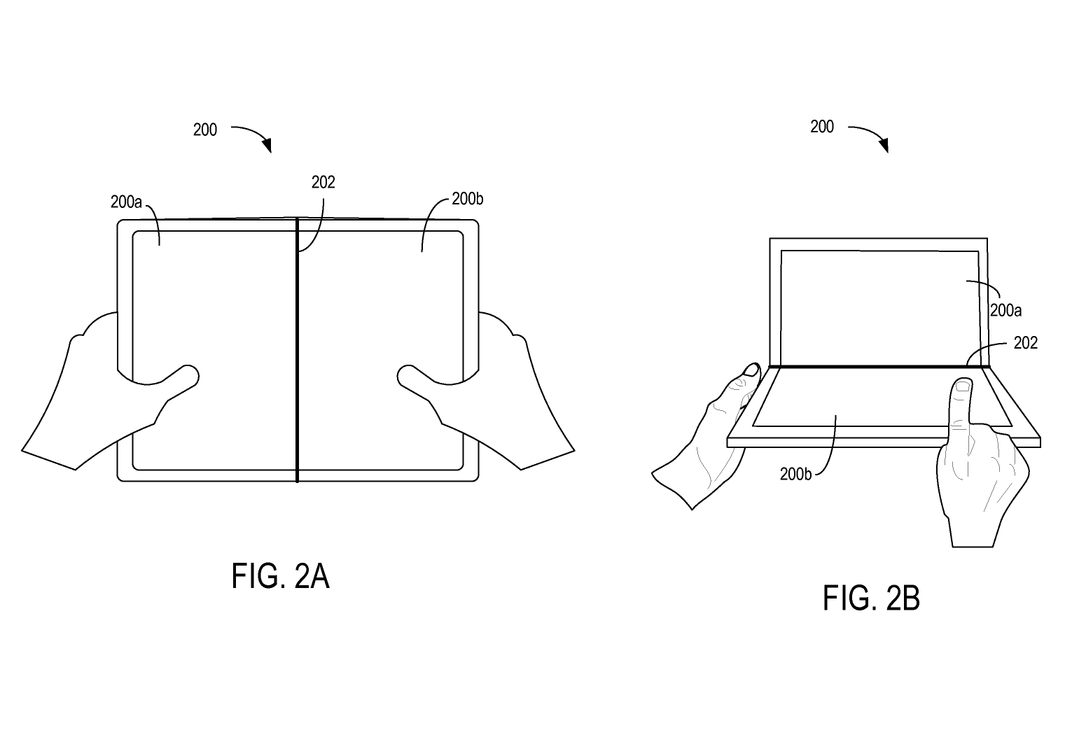

FIGS. 2A and 2B show another example of a display device that may benefit from obscuring support structures. FIGS. 2A and 2B show a hinged display device 200, which includes two display panels (200a and 200b) separated by a hinge 202. The hinge 202 may allow the display panels to be moved (e.g., rotated, angled, folded, and/or otherwise displaced) relative to one another. For example, in FIG. 2A, the display device 200 may be held in a book form, such that the two panels are mostly flat relative to one another (e.g., with an angle of approximately 180 degrees between the panels). In FIG. 2B, the display device 200 may be held in a laptop or handheld device form, such that the two panels are angled at approximately 90 degrees relative to one another. The hinge 202 may allow for any range of motion of one panel relative to the other panel. For example, the panels may be folded to close the device (e.g., with an angle of approximately 0 degrees between the panels, such that the active areas of the display panels face one another), to provide a two-sided display (e.g., with an angle of approximately 360 degrees between the panels, such that the active areas of the display panels face in opposite directions), and/or folded to any suitable degree there between. In some examples, the hinge 202 may include and/or be replaced with joints that allow for other types of movement, such as transverse movement (e.g., sliding one panel over top of the other), swinging movement (e.g., providing a ball joint that allows the panels to be split from one another and rotate freely), and/or any other movement.

As described above for the tiled display of FIG. 1, the hinged display of FIGS. 2A and 2B may include an arrangement of optical components to obscure a user's view of the hinge 202. In this manner, the user perceives a seamless or near seamless joint between two adjacent displays. One example configuration of optical components for achieving such an effect is illustrated in FIG. 3. The figure shows a cross section of an example display device 300 including a transparent protective outer layer 302 (e.g., including transparent panels 302a and 302b) that is provided over a display layer 304 (e.g., including display panels 304a and 304b). For example, the display panels may be mounted to the transparent panels and/or separated from the transparent panels via an air gap or other material (e.g., where the display panels and the transparent panels are mounted to the support structure). Display device 300 may be an example of the configuration of optical components in a display device such as display device 100 of FIG. 1 and/or display device 200 of FIGS. 2A and 2B. The transparent protective outer layer 302 may be curved in a location near a side of a support structure 306 (e.g., a joint, hinge, bracket, and/or other structural element). For example, each transparent panel may curve, angle, or otherwise be directed toward the support structure 306 to meet a bezel of the display or other support structure at the total internal reflection angle of the panel. This results in a user looking normally at the unfolded device seeing the display active area right at the edge. For example, the curved transparent protective outer layer may bend the light exiting the display panels 304a and 304b such that a user gazing in a direction of the support structure 306 instead views a region of the display panels 304a and 304b, as indicated by view lines 308.

The transparent protective outer layer 302 may comprise glass, acrylic, and/or other suitable materials that may be able to be deformed to produce the above-described curve toward an edge of the display panel/support structure. In order to enhance the effect of obscuring the support structure, the transparent panels may comprise material having a high reflective index, such as ceramic material including sapphire, Perculor, or diamond. Thus, example configuration illustrated in FIG. 3 may use any existing display panel and deform inactive components (e.g., the transparent panels) to obscure the view of the structural support. However, the example configuration illustrated in FIG. 3 results in the formation of a dip in the outer surface of the display, which may affect the aesthetics of the display device, as well as touch interaction with the device in the region of the dip (e.g., when a touch sensor is provided between the display layer 304 and the transparent protective outer layer 302). Furthermore, in order to provide the described curvature in the transparent panels, the transparent panels may be relatively thick (e.g., as compared to other displays that do not include curved transparent protective layers). The thickness of the transparent panels may provide increased protection (e.g., shock and/or shatter protection) for internal components of the display device, but may also increase a weight and overall thickness of the display device.

FIG. 4A shows a cross section of an example display device 400 that includes a substantially flat outer surface and curved internal display panels to obscure a user's view of a support structure of the device. Display device 400 may be an example of the configuration of optical components in a display device such as display device 100 of FIG. 1 and/or display device 200 of FIGS. 2A and 2B. As illustrated, display device 400 includes a transparent protective outer layer 402 that may include two or more transparent panels (e.g., 402a and 402b). Display device 400 also includes two or more display panels (e.g., 404a and 404b) for projecting light to form a displayable image. The display panels and/or transparent panels of display device 400 are separated by a support structure 406, which may include a joint, bracket, hinge, and/or other structural support. The first display panel 404a and the second display panel 404b are substantially parallel to the transparent protective outer layer 402 at respective first regions (e.g., straight regions 408a and 408b) of the first display panel and the second display panel and directed (e.g., angled, curved, or otherwise deformed) away from the transparent protective outer layer at respective second regions (e.g., curved regions 410a and 410b) of the first display panel and the second display panel. In this way, the display panel may be curved as the display panel approaches the support structure in order to direct light from the display panel toward the support structure to obscure a user's view of the support structure when viewing the display device.

To redirect light from the curved display panels to the user's eye, display device 400 includes one or more redirecting optical elements 412, including but not limited to a prism array, a cylinder Fresnel lens, a cylinder diffractive lens, and/or other diffractive optical elements and/or Fresnel lenses, which are positioned above the curved second regions 410a and 410b of the display panels. For example, a prism array may provide a regular pattern of redirecting elements, a cylinder Fresnel lens has increasing power (reducing periodicity) across the lens, and a diffractive lens may be formed similarly to a Fresnel lens, and where the steps are only a single wavelength deep, to reduce diffraction. As illustrated, the redirecting optical elements may extend from the transparent panels (as shown in solid lines) and/or be embedded/integrated into the transparent panels (as shown in dotted lines, where the deformations in the redirecting optical element may represent a bottom [e.g., display panel-facing] surface of the transparent panels). As shown by view lines 414, the redirecting optical element(s) 412 may direct light such that a viewer of the display device sees light from the display panel rather than the support structure 406 when looking near the location of the support structure. In this way, for each of the first display panel and the second display panel, the redirecting optical element extends from the support structure toward the first region of that display panel along a plane that is parallel to the first region of that display panel and terminates such that light exiting the first region of the display panel does not pass through the redirecting optical element, but light exiting the second region of the display panel does pass through the redirecting optical element.

To further obscure the support structure 406, the display device may include (e.g., in the transparent outer layer 402 and/or coupled to the display panel 404a/b) a cylinder lens. FIG. 4B shows an example configuration of a cylinder lens 414 in a display device 400b (which may be an example configuration used in display device 400 of FIG. 4A in some examples). As illustrated, the cylinder lens is positioned above display panel 416 and extends away from a support structure 418. The cylinder lens may take the form of a linear Fresnel (“cylindrical Fresnel”) or a diffractive structure (Fresnel with 1 wavelength-deep steps) only in the area where the image re-direction is used (e.g., where the display panel is curved). The cylinder lens may be differentiated from a prism array because the angle of the redirecting elements changes across the structure of the cylinder lens. The cylinder lens may cause some distortion of the image visible to the user, so the display device may use knowledge of the user's point of view to pre-correct the image for cylinder distortion. For example, the display device may include and/or be coupled to a gaze tracking system, which may determine a gaze direction and/or eye/pupil location of a user. Based on the determined gaze direction and/or eye/pupil location, the system may calculate a point of view of the user and adjust operation of the display panel to output an image that is pre-corrected for cylinder distortion.

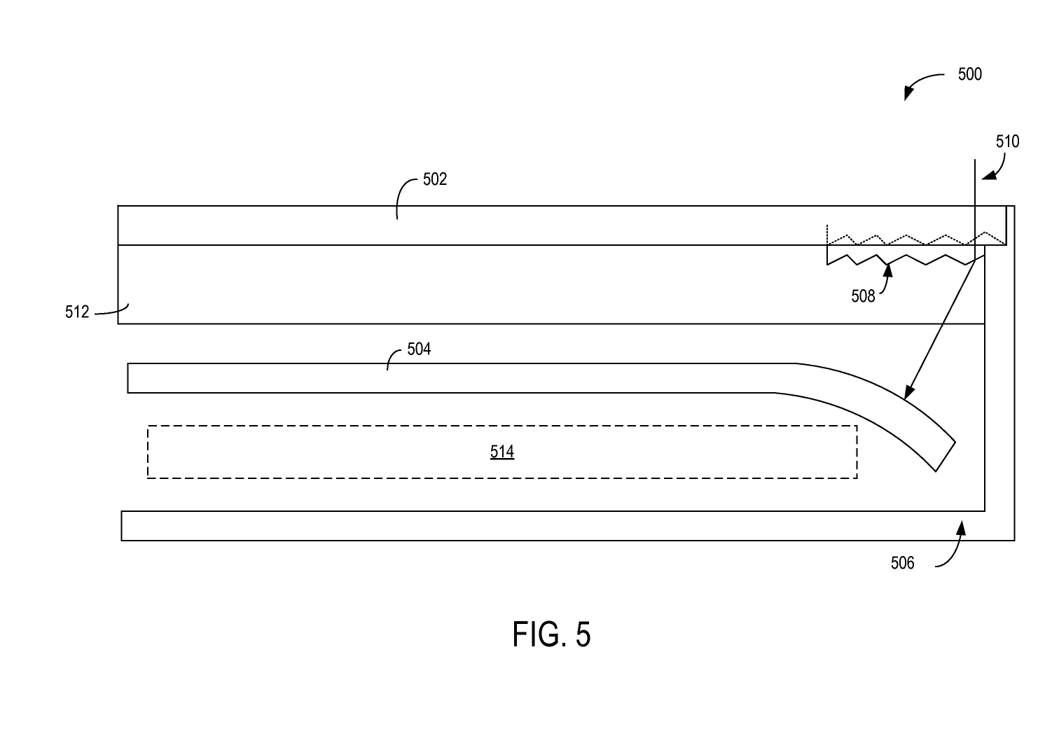

FIG. 5 shows a detailed view of a cross section of a display device 500 including at least one transparent panel 502 for protecting and transmitting light from at least one display panel 504. Display device 500 may be an example of the configuration of optical components in a display device such as display device 100 of FIG. 1 and/or display device 200 of FIGS. 2A and 2B. The display panel may be housed within a bracket 506, such as a metal or plastic bracket. As described above with respect to FIG. 4A, the display panel 504 is curved and/or otherwise directed away from the transparent panel 502 as the display panel nears a side of the bracket in order to bring the display closer to the edge of the bracket and obscure a view of the bracket when a user views the display device. A redirecting optical elements such as a diffractive optical element or Fresnel lens 508 may be embedded in or attached to the transparent panel 502 above a curved region of the display panel 504 in order to further redirect light from the display panel toward an eye of the user, as shown by view line 510.

A touch sensor 512 may be positioned between the transparent panel 502 and the display panel 504 in some examples. Although illustrated as contacting the transparent panel and being separated from the display panel via an air gap, the touch sensor may be separated from both the display panel and the transparent panel by an air gap (and/or other material), in contact with both the display panel and the transparent panel, and/or in contact with the display panel and separated from the transparent panel by an air gap (and/or other material) in other examples. The touch sensor may include optical, pressure, and/or conductive sensors for detecting objects (e.g., a finger, pen, and/or other input object) that near and/or come into contact with the transparent panel. For example, the display panel may be controlled to display a graphical user interface, and a user may provide input to the graphical user interface via the touch sensor (e.g., by touching/tapping/pressing a region of the display device that presents an interface element). Other optical components may be housed within the bracket 506. For example, a battery or other power source 514 for the display panel, touch sensor, and/or other element may be housed below the display panel 504. Accordingly, the curvature of the curved region of the display panel 504 may be sized to accommodate the battery or other power source.

As illustrated, the side of the bracket may be thicker toward a bottom of the side (e.g., toward the display panel 504) than a top of the side (e.g., toward the transparent panel 502). In this way, the separation between the transparent panel and an adjacent transparent panel and/or the edge/bezel of the display device may be minimized. The thinner region may also create a seat for housing a terminating edge of the transparent panel. In some examples, the terminating edge of the transparent panel may be bonded to the side of the bracket 506 (e.g., at the location of the illustrated seat, such that a top surface of the transparent panel is flush with a top surface of the side of the bracket). In additional or alternative examples, the display device may include an adjacent display panel and transparent panel on an opposite side of the side of the bracket illustrated in FIG. 5, and at least a portion of the transparent panel 502 may be coupled to that adjacent transparent panel (e.g., bonded thereto). In some examples, at least a portion of the transparent panel (e.g., half of the illustrated thickness—where thickness is the height of the transparent panel in the illustrated cross-section) may be continuous across the top of the side of the bracket and the transparent panel may additionally cover an adjacent display panel (e.g., where the region of the transparent panel that covers the adjacent display panel is at the illustrated thickness). The bracket may be a portion of a chassis of the device, and the joint between the chassis of the device and the transparent panel may be a bevel-butt joint at an appropriate angle in some examples.

In some examples, the illustrated side of the bracket 506 may be an edge of the display device 500. In such examples, the display panel 504 may be the only display panel in the display device. In other examples, the display panel 504 may be one of a plurality of display panels in the display device. The illustrated display panel includes a straight region and a curved region, where the curved region is near the side of the bracket. The display panel may include a second curved region on an opposite side of the straight region from the first (illustrated) curve region in some examples (e.g., such that the straight region forms a middle of the active region of the display panel, and each terminating end of the display panel is curved toward a side of the bracket 506). In such examples, one or both sides of the bracket may form an edge of the display device and/or a joint/hinge between the illustrated display panel and an adjacent display panel.

By curving a display panel as described herein toward a support structure of a display device, the mechanical border of the display device and/or display panels of the display device may be effectively hidden or obscured from a user's view while maintaining a flat outer surface (e.g., for unobstructed touch input detection). In this way, a display device may be configured to appear to have a smaller edge/border between display panels than the edge/border that is actually present. Accordingly, structural integrity may be maintained while increasing an effective display area.

In some embodiments, the methods and processes described herein may be tied to a computing system of one or more computing devices. In particular, such methods and processes may be implemented as a computer-application program or service, an application-programming interface (API), a library, and/or other computer-program product.

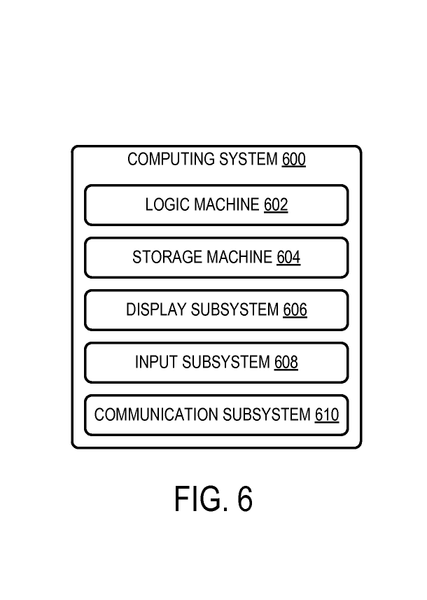

FIG. 6 schematically shows a non-limiting embodiment of a computing system 600 that can enact one or more of the methods and processes described above. Computing system 600 is shown in simplified form. Computing system 600 may take the form of one or more display devices, head-mounted display devices, personal computers, server computers, tablet computers, home-entertainment computers, network computing devices, gaming devices, mobile computing devices, mobile communication devices (e.g., smart phone), and/or other computing devices. In some examples, computing system 600 may include and/or provide display instructions to one or more of the display devices described above (e.g., display device 300 of FIG. 3, display device 400 of FIG. 4A, and/or display device 500 of FIG. 5).

Computing system 600 includes a logic machine 602 and a storage machine 604. Computing system 600 may optionally include a display subsystem 606, input subsystem 608, communication subsystem 610, and/or other components not shown in FIG. 6.

Logic machine 602 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 604 includes one or more physical devices configured to hold instructions executable by the logic machine to implement the methods and processes described herein. When such methods and processes are implemented, the state of storage machine 604 may be transformed—e.g., to hold different data.

Storage machine 604 may include removable and/or built-in devices. Storage machine 604 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 604 may include volatile, nonvolatile, dynamic, static, read/write, read-only, random-access, sequential-access, location-addressable, file-addressable, and/or content-addressable devices.

It will be appreciated that storage machine 604 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 602 and storage machine 604 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 600 implemented to perform a particular function. In some cases, a module, program, or engine may be instantiated via logic machine 602 executing instructions held by storage machine 604. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service”, as used herein, is an application program executable across multiple user sessions. A service may be available to one or more system components, programs, and/or other services. In some implementations, a service may run on one or more server-computing devices.

When included, display subsystem 606 may be used to present a visual representation of data held by storage machine 604. For example, the display subsystem 606 may include one or more of the display devices described above (e.g., display device 300 of FIG. 3, display device 400 of FIG. 4A, and/or display device 500 of FIG. 5). The visual representation may take the form of a graphical user interface (GUI). As the herein described methods and processes change the data held by the storage machine, and thus transform the state of the storage machine, the state of display subsystem 606 may likewise be transformed to visually represent changes in the underlying data. Display subsystem 606 may include one or more display devices utilizing virtually any type of technology. Such display devices may be combined with logic machine 602 and/or storage machine 604 in a shared enclosure, or such display devices may be peripheral display devices.

When included, input subsystem 608 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 610 may be configured to communicatively couple computing system 600 with one or more other computing devices. Communication subsystem 610 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 600 to send and/or receive messages to and/or from other devices via a network such as the Internet.

An example display device includes a transparent outer layer including a first transparent panel and a second transparent panel, a display layer comprising a first display panel and a second display panel, a gap positioned between the first display panel and the second display panel, a first redirecting optical element positioned between the first transparent panel and the first display panel, and a second redirecting optical element positioned between the second transparent panel and the second display panel. Such an example additionally or alternatively includes the example display device wherein a first region of the first display is located beneath the first redirecting optical element and the first region is curved. Such an example additionally or alternatively includes the example display device wherein, for each of the first display panel and the second display panel, the redirecting optical element extends from the gap toward a second region of that display panel along a plane that is parallel to the second region of that display panel and terminates such that light exiting the second region of the display panel does not pass through the first redirecting optical element. Such an example additionally or alternatively includes the display device wherein the first redirecting element is configured to direct light emitted from the first region of the first display panel toward an eye of a user of the display device. Such an example additionally or alternatively includes the display device wherein the first display panel and the second display panel are substantially parallel to the first transparent panel and the second transparent panel, respectively, at respective first regions and directed away from the first and second transparent panel, respectively, at respective second regions, the first regions of the first and second display panel being further from the gap than the second regions of the first and second display panels. Such an example additionally or alternatively includes the display device wherein the second regions of the first and second display panels are shorter than the first regions of the first and second display panels. Such an example additionally or alternatively includes the display device further comprising a battery for powering the display device, the battery being located on an opposite side of one or more of the first display panel and the second display panel from the transparent outer layer. Such an example additionally or alternatively includes the display device wherein the first redirecting optical element and the second redirecting optical element each includes one of a prism array, a cylinder Fresnel lens, or a cylinder diffractive lens for obscuring the gap from a view of a user of the display device. Such an example additionally or alternatively includes the display device wherein the display layer further comprises a third display panel positioned adjacent to the first display panel with a second gap positioned there between, the first display panel having a second region that curves. Such an example additionally or alternatively includes the display device wherein the first region curves opposite to the second region. Such an example additionally or alternatively includes the display device wherein the gap includes a hinge positioned therein such that the first display panel is moveable relative to the second display panel. Any or all of the above-described examples may be combined in any suitable manner in various implementations.

Another example display device includes a transparent outer layer for protecting internal components of the display device, a display layer comprising a display panel, the display panel being substantially parallel to the transparent outer layer at a first region and curved away from the transparent outer layer at a second region, a support structure housing the first display panel, the support structure including a first side positioned at a terminating end of the transparent outer layer and terminating end of the second region of the display panel, and a redirecting optical element positioned between the transparent outer layer and the first display panel. Such an example additionally or alternatively includes the display device wherein a side surface of the transparent outer layer is coupled to a side surface of the first side of the support structure, a top surface of the transparent outer layer being parallel to a top surface of the first side of the support structure. Such an example additionally or alternatively includes the display device wherein the top surface of the first side of the support structure is flush with the top surface of the transparent outer layer. Such an example additionally or alternatively includes the display device wherein the top surface of the first side of the support structure is positioned below the top surface of the transparent outer layer and above a bottom surface of the transparent outer layer. Such an example additionally or alternatively includes the display device wherein the first side of the support structure is thicker in a bottom region than a top region, the bottom region being nearer to the display panel than the top region. Such an example additionally or alternatively includes the display device wherein the first side of the support structure comprises an edge of the display device. Such an example additionally or alternatively includes the display device wherein the display panel is a first display panel, and wherein the first side of the support structure comprises a joint or hinge between the first display panel and a second display panel. Such an example additionally or alternatively includes the display device wherein the transparent outer layer comprises a first transparent outer layer, the display device further comprising a second transparent outer layer positioned above the second display panel and on an opposite side of the joint or hinge from the first transparent outer layer. Such an example additionally or alternatively includes the display device further comprising a touch sensor positioned between the transparent outer layer and the display panel. Any or all of the above-described examples may be combined in any suitable manner in various implementations.

Another example display device includes a transparent outer layer for protecting internal components of the display device, the transparent outer layer comprising a first transparent panel and a second transparent panel, a display layer comprising a first display panel and a second display panel, a hinge positioned between the first display panel and the second display panel, the first display panel being moveable relative to the second display panel, the first display panel being substantially parallel to the first transparent panel at a first region of the first display panel and curved away from the first transparent panel at a second region of the first display panel, and the second display panel being substantially parallel to the second transparent panel at a first region of the second display panel and curved away from the second transparent panel at a second region of the second display panel, a first redirecting optical element positioned between the first transparent panel and the second region of the first display panel, and a second redirecting optical element positioned between the second transparent panel and the second region of the second display panel. Such an example additionally or alternatively includes the display device wherein a first region of the hinge is positioned between the first transparent panel and the second transparent panel and a second region of the hinge is positioned between the first display panel and the second display panel, the first region of the hinge being thinner than the second region of the hinge. Any or all of the above-described examples may be combined in any suitable manner in various implementations.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A display device comprising:
a transparent outer layer including a first transparent panel and a second transparent panel;
a display layer comprising a first display panel and a second display panel;
a gap positioned between the first display panel and the second display panel;
a first redirecting optical element positioned between the first transparent panel and the first display panel; and
a second redirecting optical element positioned between the second transparent panel and the second display panel.

2. The display device of claim 1, wherein a first region of the first display is located beneath the first redirecting optical element and the first region is curved.

3. The display device of claim 2, wherein, for each of the first display panel and the second display panel, the redirecting optical element positioned between the transparent outer layer and that display panel extends from the gap toward a second region of that display panel along a plane that is parallel to the second region of that display panel and terminates such that light exiting the second region of the display panel does not pass through the first redirecting optical element.

4. The display device of claim 2, wherein the first redirecting optical element is configured to direct light emitted from the first region of the first display panel toward an eye of a user of the display device.

5. The display device of claim 1, further comprising a battery for powering the display device, the battery being located on an opposite side of one or more of the first display panel and the second display panel from the transparent outer layer.

6. The display device of claim 1, wherein the first redirecting optical element and the second redirecting optical element each includes one of a prism array, a cylinder Fresnel lens, or a cylinder diffractive lens for obscuring the gap from a view of a user of the display device.

7. The display device of claim 1, wherein the display layer further comprises a third display panel positioned adjacent to the first display panel with a second gap positioned there between, the first display panel having a second region that curves.

8. The display device of claim 7, wherein the first region curves opposite to the second region.

9. The display device of claim 1, wherein the gap includes a hinge positioned therein such that the first display panel is moveable relative to the second display panel.

10. A display device comprising:
a transparent outer layer for protecting internal components of the display device;
a display layer comprising a display panel, the display panel being substantially parallel to the transparent outer layer at a first region and curved away from the transparent outer layer at a second region;
a support structure housing the first display panel, the support structure including a first side positioned at a terminating end of the transparent outer layer and terminating end of the second region of the display panel; and
a redirecting optical element positioned between the transparent outer layer and the first display panel.

11. The display device of claim 10, wherein a side surface of the transparent outer layer is coupled to a side surface of the first side of the support structure, a top surface of the transparent outer layer being parallel to a top surface of the first side of the support structure.

12. The display device of claim 11, wherein the top surface of the first side of the support structure is flush with the top surface of the transparent outer layer.

13. The display device of claim 11, wherein the top surface of the first side of the support structure is positioned below the top surface of the transparent outer layer and above a bottom surface of the transparent outer layer.

14. The display device of claim 10, wherein the first side of the support structure is thicker in a bottom region than a top region, the bottom region being nearer to the display panel than the top region.

15. The display device of claim 10, wherein the first side of the support structure comprises an edge of the display device.

16. The display device of claim 10, wherein the display panel is a first display panel, and wherein the first side of the support structure comprises a joint or hinge between the first display panel and a second display panel.

17. The display device of claim 16, wherein the transparent outer layer comprises a first transparent outer layer, the display device further comprising a second transparent outer layer positioned above the second display panel and on an opposite side of the joint or hinge from the first transparent outer layer.

18. The display device of claim 10, further comprising a touch sensor positioned between the transparent outer layer and the display panel.

19. A display device comprising:
a transparent outer layer for protecting internal components of the display device, the transparent outer layer comprising a first transparent panel and a second transparent panel;
a display layer comprising a first display panel and a second display panel;
a hinge positioned between the first display panel and the second display panel, the first display panel being moveable relative to the second display panel, the first display panel being substantially parallel to the first transparent panel at a first region of the first display panel and curved away from the first transparent panel at a second region of the first display panel, and the second display panel being substantially parallel to the second transparent panel at a first region of the second display panel and curved away from the second transparent panel at a second region of the second display panel;
a first redirecting optical element positioned between the first transparent panel and the second region of the first display panel; and
a second redirecting optical element positioned between the second transparent panel and the second region of the second display panel.

20. The display device of claim 19, wherein a first region of the hinge is positioned between the first transparent panel and the second transparent panel and a second region of the hinge is positioned between the first display panel and the second display panel, the first region of the hinge being thinner than the second region of the hinge.
